(19) United States
(12) Patent Application Publication
(10) Pub. No.: US 2023/0126599 A1
(43) Pub. Date: Apr. 27, 2023

(54) DISPLAY MEDIUM, PROCESSING DEVICE, AND PROGRAM

(71) Applicant: DWANGO Co., Ltd., Tokyo (JP)

(72) Inventor: Kaisei SAKURAI, Tokyo (JP)

(73) Assignee: DWANGO Co., Ltd., Tokyo (JP)

(21) Appl. No.: 17/908,620

(22) PCT Filed: Aug. 25, 2021
(86) PCT No.: PCT/JP2021/031163

§ 371 Date: Sep. 1, 2022

(30) Foreign Application Priority Data
Sep. 11, 2020 (JP) 2020-153221

(51) Int. Cl. G06F 30/10

(52) U.S. Cl. CPC G06F 30/10; G09F 19/14

(57) ABSTRACT

This display medium includes: a base material having a three-dimensional shape; and a partition P having, on the surface of the base material, a surface that radially divides a space on the surface of the base material in each of a plurality of directions. A portion that is exposed when the display medium is observed from a prescribed direction among the plurality of directions is imparted with the color of content that corresponds to the prescribed direction.

### FIELD

The present invention relates to a display medium, a processing device, and a program.

### BACKGROUND

A display medium displaying images different from each other in a manner that depends on a direction easily draws the attention of an observer, thereby being used in advertising posters, cards, and the like. In order to produce such a display medium, in general, a special device and special equipment are required.

In order to attain efficient information display with the display medium, there is a display medium that is capable of displaying a plurality of information pieces (refer to Patent Document 1). According to the invention described in Patent Document 1, a planar member applied with a color is divided into a plurality of sub-cells, and a protrusion member allowing the color of the sub-cell to be visually recognized is formed on the planar member. The protrusion member is formed parallel to a designated direction on the planar member and perpendicular to the planar member. In a case where the display medium is observed from the designated direction, a color applied to the sub-cell parallel to the designated direction is observed from the designated direction.

### Patent Document

Patent Document 1: Japanese Patent No. 6,374,625

### SUMMARY OF THE INVENTION

In the display medium described in Patent Document 1, the color of the protrusion member is a monochromatic color, and thus, a color range is narrow. In addition, content is displayed with some colors provided on the planar member, and thus, the luminance of each content piece displayed by the display medium may decrease. In addition, Patent Document 1 discloses only the fact that the display medium is formed on a flat surface, but not the fact that the display medium has a three-dimensional shape.

Accordingly, an object of the invention is to provide a technology relevant to a display medium having a three-dimensional shape that is capable of displaying a plurality of content pieces with a wide color range and a high luminance.

In order to attain the object described above, the first feature of the invention relates to a display medium, including: a base material having a three-dimensional shape; and a partition having a surface that radially divides a space on a surface of the base material in each of a plurality of directions, on the surface of the base material, in which a portion that is exposed when the display medium is observed from a prescribed direction among the plurality of directions is imparted with a color of content corresponding to the prescribed direction.

The partition may have a surface that radially divides the space on the surface of the base material in each direction in which the partition is visually recognized, among the plurality of directions.

The partition may be formed in a cell that is provided on a surface of the three-dimensional shape, and a structure of the partition may include a part of a Voronoi surface in a Voronoi diagram using a point virtually provided on a line connecting points on the direction and the cell as a generatrix.

The second feature of the invention relates to a processing device calculating a color that is imparted to the display medium according to the first feature, in which a surface of the display medium is virtually divided into a plurality of sub-cells, a sub-cell that is visually recognized from each of the plurality of directions is specified, and the processing device includes: a color determination unit determining a color that is imparted to the sub-cell such that a color formed by each color of the sub-cell visually recognized from each of the plurality of directions is close to a color of a portion of content corresponding to each of the plurality of directions.

The third feature of the invention relates to a program for calculating a color that is imparted to the display medium according to the first feature, in which a surface of the display medium is virtually divided into a plurality of sub-cells, a sub-cell that is visually recognized from each of the plurality of directions is specified, and the program allows a computer to function as: a color determination unit determining a color that is imparted to the sub-cell such that a color formed by each color of the sub-cell visually recognized from each of the plurality of directions is close to a color of a portion of content corresponding to each of the plurality of directions.

The fourth feature of the invention relates to a processing device determining a position in which a plurality of components are provided, on a surface of a base material having a three-dimensional shape, the device including: a memory device storing base material shape data for specifying a shape of the base material, and pack data for specifying a shape of a plurality of packs including the plurality of components, respectively, and a reference position that is provided on the surface of the base material, in the pack; a packing unit arranging a reference position of one pack on the surface of the base material, with reference to the base material shape data and the pack data, executing processing of arranging the pack on the surface of the base material by using one pack that is already arranged as a reference pack to be in contact with the reference pack until a new pack in contact with the reference pack is not capable of being arranged, and repeating the processing until a new pack in contact with the pack that is already arranged is not capable of being arranged; and a position calculation unit calculating a position in which the component is provided such that a surface of the component is positioned in the reference position of the pack, in accordance with a position of the pack arranged by the packing unit.

The fifth feature of the invention relates to a program for determining a position in which a plurality of components are provided, on a surface of a base material having a three-dimensional shape, the program allowing a computer to function as: a memory unit storing base material shape data for specifying a shape of the base material, and pack data for specifying a shape of a plurality of packs including the plurality of components, respectively, and a reference position that is provided on the surface of the base material, in the pack; a packing unit arranging a reference position of one pack on the surface of the base material, with reference to the base material shape data and the pack data, executing processing of arranging the pack on the surface of the base material by using one pack that is already arranged as a reference pack to be in contact with the reference pack until a new pack in contact with the reference pack is not capable of being arranged, and repeating the processing until a new pack in contact with the pack that is already arranged is not capable of being arranged; and a position calculation unit calculating a position in which the component is provided such that a surface of the component is positioned in the reference position of the pack, in accordance with a position of the pack arranged by the packing unit.

The sixth feature of the invention relates to a processing device specifying a shape of a model in which a plurality of components are added to a base material, the device including: a memory device storing shape data for specifying a shape of the base material, component shape data for specifying a shape of each of the components, and component position data for specifying a position in the base material to which the component is added; an intersection specifying unit specifying a component intersecting with a shape of the other component when the component is added to the position specified by the component position data; and a changing unit changing a position to which the specified component is added to a position not intersecting with the shape of the other component.

When there is not position to which the specified component is not added, the changing unit may delete the specified component.

The processing device may further include: a generating unit generating shape data of the model by a sum-set operation of the shape of the base material, a position to which each of the components after being changed by the changing unit is added, and the shape of each of the components.

The seventh feature of the invention relates to a program for specifying a shape of a model in which a plurality of components are added to a base material, the program allowing a computer to function as: a memory unit storing shape data for specifying a shape of the base material, component shape data for specifying a shape of each of the components, and component position data for specifying a position in the base material to which the component is added; an intersection specifying unit specifying a component intersecting with a shape of the other component when the component is added to the position specified by the component position data; and a changing unit changing a position to which the specified component is added to a position not intersecting with the shape of the other component.

According to the invention, it is possible to provide a technology relevant to a display medium having a three-dimensional shape that is capable of displaying a plurality of content pieces with a wide color range and a high luminance.

### BRIEF DESCRIPTION OF THE DRAWINGS

FIG. 1 is a top view of a cell and a partition that are used in a display medium according to an embodiment of the invention.

FIG. 2 is a perspective view of the partition according to the embodiment of the invention.

FIG. 3 is a diagram illustrating the cell that is provided in a base material of the display medium according to the embodiment of the invention.

FIG. 4 is a diagram illustrating an example of the display medium according to the embodiment of the invention.

FIG. 5 is a diagram illustrating the partition according to the embodiment of the invention.

FIG. 6 is a diagram illustrating an example of a target image that is displayed in each direction by the display medium according to the embodiment of the invention.

FIG. 7 is a diagram illustrating an example of an output image that is displayed in each direction by the display medium according to the embodiment of the invention.

FIG. 8 is a diagram illustrating a hardware configuration and a functional block of a processing device according to the embodiment of the invention.

FIG. 9 is a diagram illustrating a functional block of a shape specifying unit of the processing device according to the embodiment of the invention.

FIG. 10 is a diagram illustrating packing processing according to the embodiment of the invention.

FIG. 11 is a flowchart illustrating the packing processing according to the embodiment of the invention.

FIG. 12 is a diagram illustrating the base material having a three-dimensional shape in the embodiment of the invention, and a state in which the base material is subjected to the packing processing.

FIG. 13 is a flowchart illustrating partition shape specifying processing according to the embodiment of the invention.

FIG. 14 is a flowchart illustrating the shape specifying processing according to the embodiment of the invention.

FIG. 15 is a flowchart illustrating color determination processing according to the embodiment of the invention.

### DETAILED DESCRIPTION

Next, embodiments of the invention will be described with reference to the drawings. In the description of the drawings, the same or similar reference numerals will be applied to the same or similar parts.

### DISPLAY MEDIUM

A display medium 1 according to an embodiment of the invention has an arbitrary three-dimensional shape, and displays content pieces different from each other in a plurality of directions. The display medium 1 includes a base material 2 having a three-dimensional shape, and a partition P having a surface that radially divides a space on the surface of the base material 2 in each of the plurality of directions, on the surface of the base material 2.

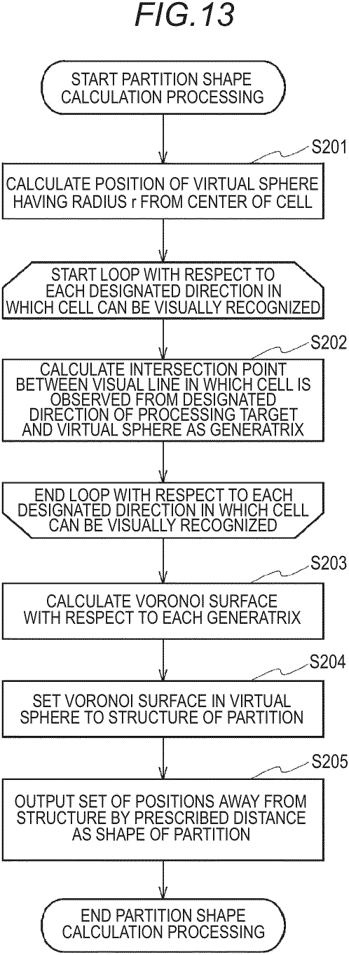

It is sufficient that the base material 2 of the display medium 1 has an arbitrary shape including a three-dimensional shape. The base material 2, for example, is in the shape of a rabbit as illustrated in FIG. 12(a), but is not limited thereto. In the embodiment of the invention, a case is described in which the partition P is not provided on the bottom surface such that the display medium 1 can be provided on a stand or the like, but it is sufficient that the partition is not provided in a portion that is exposed when the display medium 1 is visually recognized.

The display medium 1 is formed to be capable of displaying the content pieces different from each other in the plurality of directions. The display medium 1 is capable of displaying different content pieces in each direction by observing the display medium from each prescribed direction.

In the embodiment of the invention, the direction in which the display medium 1 displays the content will be referred to as a designated direction. In addition, a direction in which the display medium 1 is visually recognized from an observing point on the designated direction will be referred to as an eye direction. Note that, in the embodiment of the invention, the designated direction in which the content can be displayed may be within a prescribed angle range with respect to the display medium 1.

The content that is displayed in each of the designated directions by the display medium 1 is an arbitrary still image. The display medium 1 is capable of displaying arbitrary content in each of the designated directions. There is no limit such that structural outlines are similar, or a subject or a part of the subject is common in a plurality of content pieces displayed by the display medium 1. The display medium 1 is capable of displaying arbitrary content indicating different semantic contents in each of the designated directions. Accordingly, a user who visually recognizes the display medium 1 is capable of understanding different information pieces from each of the content pieces displayed in each of the designated directions, and thus, the display medium 1 is capable of transmitting a lot of information.

In the embodiment of the invention, each of the content pieces displayed in the designated direction is an arbitrary still image, and has subjects different from each other. In the embodiment of the invention, the subject is a tangible entity, a letter, a symbol, a number, or the like that is expressed by the content, and is a mass of pixels expressing an object. The subject may be displayed vividly with respect to the background. In the embodiment of the invention, each of the content pieces displayed in each of the designated directions is capable of including subjects having completely different colors, shapes, and the like but not a subject plurality of subjects of which an overlapping direction is changed or modified. In the embodiment of the invention, content displayed in one designated direction is capable of including a letter in the solid-color background, and content expressed in the other designated direction is capable of including the images of people in the background of an urban area.

Note that, the user who visually recognizes the display medium 1 from a direction away from any designated direction may visually recognize content that is different from the content intended by the display medium 1. The content that is different from the content intended by the display medium 1 is content that is not intended for the user to understand prescribed information from display contents of the content, and in many cases, is content that is difficult for the user to understand the meaning from the content.

In a case where the display medium 1 is observed from the space on the display medium 1 while changing an eye position, there is a position in which the meaning can be understood from the content displayed by the display medium 1, and there is also a position in which the meaning is not capable of being understood. The position in which the meaning can be understood from the content is a position on any one designated direction among a plurality of designated directions assumed by the display medium 1, or a position in the vicinity of any one designated direction.

### Partition

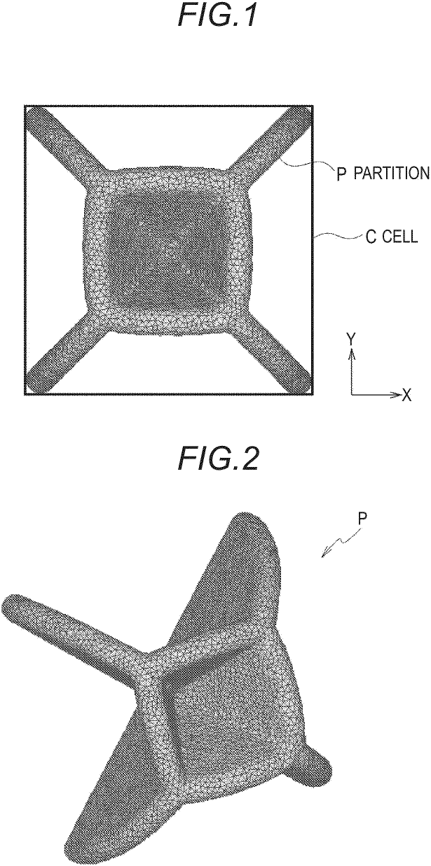

The partition P of the display medium 1 according to the embodiment of the invention will be described with reference to FIG. 1 and FIG. 2. As illustrated in FIG. 1, the partition P is provided in each cell C.

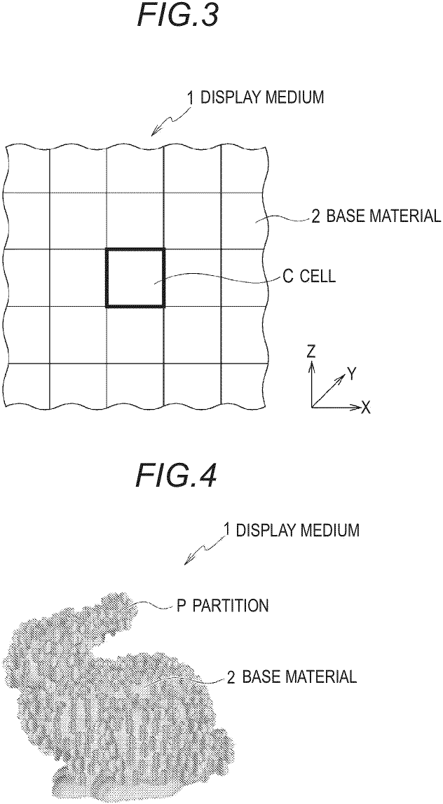

As illustrate in FIG. 3, the display medium 1 includes the base material 2. The base material 2 may perform diffused reflection.

In the embodiment of the invention, the base material 2 has a three-dimensional shape, and a plurality of cells C are formed on the surface of the three-dimensional shape. The cell C may be virtually formed, or the adjacent cells C may not be visually discriminated. In an example illustrated in FIG. 3, the surface of the base material 2 is an XY flat surface and is provided outside the base material 2. The surface of the base material 2 may be formed as a flat surface, or may be formed as a curved surface. In the example illustrated in FIG. 3, the cell C may have a rectangular shape, but may have an arbitrary shape such as a circular shape. In addition, a case is described in which the base material 2 is paved with the cells C without omission, but a region other than the cell may be provided between the cells C.

In the embodiment of the invention, there are light sources in all directions. A color that is imparted to the display medium 1 is isotropically diffused in all directions.

The partition P illustrated in FIG. 1 and FIG. 2 is formed in each of the cells C formed on the surface of the base material 2 of the display medium 1. When the display medium 1 is observed from a prescribed designated direction, content corresponding to the observing point is expressed by a color that is imparted to the surface of the partition P facing the eye direction and a color that is imparted to the surface of the base material 2.

The partition P is formed in the cell C. The partition P is a surface that is formed on a surface intersecting with the surface of the base material 2, and has a portion that is exposed when the display medium 1 is observed from each of the plurality of directions. The base material 2 and the partition P, for example, include an ultraviolet (UV) curable resin with a pigment, and a member having shielding properties, such as plaster. In an example illustrated in FIG. 1, the partition P is provided to be in contact with the outer edge of the cell C.

As illustrated in FIG. 4, the partition P has a convex shape that is bulged to the outside of the surface of the base material 2. A surface portion other than a portion in which the partition P is in contact with the base material 2 is imparted with the color expressing the content. The display medium 1 according to the embodiment of the invention is imparted with the color of the content in a convex shape with respect to the surface of the base material 2, and thus, an area to which the color of the content is imparted increases compared to a case where the color of the content is imparted only to the base material. Even in a case of displaying a plurality of content pieces by one medium, the display medium 1 including such a partition P is capable of forming a wide area expressing each of the content pieces, and thus, it is possible to display the content with a wide color range and a high luminance.

In addition, in the embodiment of the invention, on the surface of the base material 2, the surface portion other than the portion in which the partition P is in contact with the base material 2 is imparted with the color expressing the content. Accordingly, a wide area expressing each of the content pieces can be formed.

As illustrated in FIG. 1 and FIG. 2, the partition P has a plurality of surfaces. The partition P has one or more surfaces with respect to one designated direction of the display medium 1. The surface faces the eye direction in which the display medium 1 is visually recognized from the observing point on one designated direction, and is exposed when the display medium 1 is visually recognized from the observing point. The color of content corresponding to the designated direction is expressed on the surface that is exposed in the designated direction.

More specifically, the portion that is exposed when the display medium 1 is observed from the prescribed direction among the plurality of directions is imparted with the color of the content corresponding to the prescribed direction, on the surface of the partition P. In each of the designated directions of the display medium 1, when the display medium 1 is observed from the designated direction, a part of the surface of the partition P is exposed in the designated direction, and the exposed portion is imparted with the color of the content corresponding to the designated direction. Accordingly, the partition P has the plurality of surfaces, and thus, a part of the content corresponding to each of the designated directions can be expressed in a plurality of designated directions.

In the embodiment of the invention, the partition P has a surface that radially divides the space on the surface of the base material 2, in each direction in which the partition is visually recognized, among the plurality of directions. In the embodiment of the invention, since the display medium 1 has the three-dimensional shape, there is a limit in the direction in which the partition P is visually recognized, in accordance with a position in which the partition P is provided. In an example illustrated in FIG. 12(a), one point on the head of a rabbit can be visually recognized from the side or the top, but one point on the body of the rabbit is not capable of being visually recognized from a side opposite to the point. Therefore, the partition P is formed to have a surface for expressing content in a direction in which the partition P can be visually recognized, for each position in which the partition P is provided.

Note that, the portion that is exposed in the prescribed designated direction may also be exposed in another designated direction. As described above, a portion that is exposed in the plurality of designated directions is imparted with colors suitable for the plurality of content pieces corresponding to the plurality of designated directions.

The partition P illustrated in FIG. 1 and FIG. 2 is imparted with colors of five content pieces corresponding to five designated directions. Five designated directions are a direction of an azimuth angle of 0 degrees and an elevation angle of 45 degrees, a direction of an azimuth angle of 90 degrees and an elevation angle of 45 degrees, a direction of an azimuth angle of 180 degrees and an elevation angle of 45 degrees, and a direction of an azimuth angle of 270 degrees and an elevation angle of 45 degrees, in addition to a normal direction with respect to the base material 2 of the cell C. Here, the azimuth angle indicates an azimuth direction on the XY flat surface of the base material 2 of the cell C, and the elevation angle indicates an angle between the XY flat surface of the base material 2 of the cell C and a visual line of looking up one point in a Z direction from the XY flat surface.

In the example illustrated in FIG. 1 and FIG. 2, the partition P has 16 triangular surfaces facing a plurality of visual lines. The partition P has four triangular surfaces with respect to the normal direction with respect to the base material 2 of the cell C. A part of content corresponding to the normal direction is expressed such four surfaces. In addition, the partition P has three triangular surfaces in each of four directions other than the normal direction. A part of content corresponding to each of the directions is expressed by each of three surfaces.

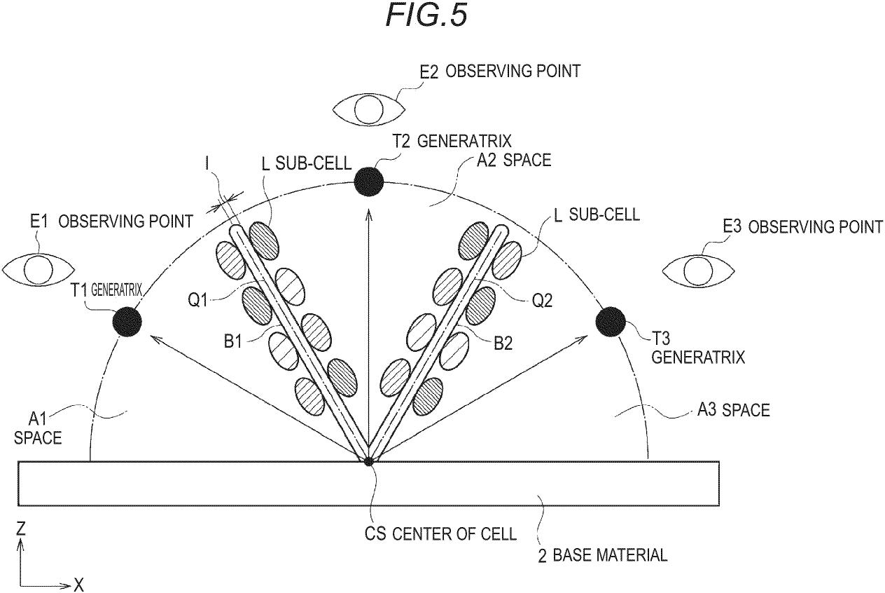

The shape of the partition P will be described with reference to FIG. 5. In the embodiment of the invention, a Voronoi diagram with respect to a generatrix that is virtually provided on the designated direction is virtually formed. The structure of the partition P includes a part of a Voronoi surface in the Voronoi diagram using a point that is virtually provided on a line connecting points on the designated direction and the cell C as a generatrix. The partition P is obtained by fleshing out the Voronoi surface that is the structure. The surface of the partition P has a surface parallel to the Voronoi surface.

In an example illustrated in FIG. 5, three observing points E1, E2, and E3 are provided. Generatrices T1, T2, and T3 are provided on the visual line when a center Cs of the cell C is visually recognized from each of the observing points E1, E2, and E3. The generatrices T1, T2, and T3 are provided on a virtual sphere having a prescribed radius centered on the center Cs of the cell C.

The partition P has one or more shielding members B. The shielding member B has the Voronoi surface as a structure, and is obtained by fleshing out the Voronoi surface. The shielding member B divides the space on the cell C in which the partition P is provided into regions in each of the designated directions.

In the example illustrated in FIG. 5, the partition P has shielding members B1 and B2. The shielding member B1 has a Voronoi surface Q1 as a structure, and is fleshed out by a thickness of 1. The shielding member B2 has a Voronoi surface Q2 as a structure, and is fleshed out by a thickness of 1. In addition, the tip of the shielding member B1 is formed into the shape of a circle having a radius of 1.

The shielding member B1 divides the space on the cell C into a space A1 corresponding to the observing point E1 and a space A2 corresponding to the observing point E2. The shielding member B2 divides the space on the cell C into the space A2 corresponding to the observing point E2 and a space A3 corresponding to the observing point E3.

The portion that is exposed when the display medium 1 is observed from the prescribed designated direction among the plurality of designated directions, on the surface of the partition P, includes a portion that is shielded in a case where the display medium 1 is observed from a direction other than the prescribed designated direction among the plurality of designated directions. Even in a case where the surface of the partition P is exposed in one or more prescribed designated directions, the surface may not be seen from the other designated directions. The surface of the partition P expresses the color of content corresponding to the designated direction in which the surface is exposed. Accordingly, the display medium 1 is capable of expressing a part of different content in the plurality of designated directions, and thus, is capable of displaying the plurality of content pieces with a wide color range and a high luminance.

In the example illustrated in FIG. 5, the surface of the shielding member B1 on the space A1 side has a portion that can be visually recognized from the observing point E1, but is not capable of being visually recognized from the observing point E2 or the observing point E3. The surface of the shielding member B1 on the space A2 side has a portion that can be visually recognized from the observing point E2, but is not capable of being visually recognized from the observing point E1 or the observing point E3. The surface of the shielding member B2 on the space A2 side has a portion that can be visually recognized from the observing point E2, but is capable of being visually recognized from the observing point E1 or the observing point E3. The surface of the shielding member B2 on the space A3 side has a portion that can be visually recognized from the observing point E3, but is not capable of being visually recognized from the observing point E1 or the observing point E2.

Each of the surfaces of the partition P is formed such that the surface is likely to be visually recognized from the designated direction and is less likely to be visually recognized from the other designated directions. Each of the surfaces of the partition P makes an effect of emitting colors that form the content in the designated direction and an effect of shielding light from the other designated directions compatible. Accordingly, the display medium 1 is capable of displaying arbitrary different content pieces in each of the designated directions. In addition, the display medium 1 is capable of displaying content with a wide color range and a high luminance in each of the designated directions. Since each of the surfaces of the partition P is prevented from being affected by the visual line from directions other than the designated direction, a suitable color can be imparted to the surface that is observed from the designated direction.

In the embodiment of the invention, the structure of the partition P is formed on the Voronoi surface formed with respect to the generatrix. The Voronoi surface is formed to pass through the center between the adjacent generatrices among the generatrices and to shield the visual line from each of the generatrices. The surface of the partition P is formed to have a prescribed thickness with respect to the Voronoi surface formed as described above.

By imparting a color to the surface of the partition P formed as described above, it is possible to impart the color of the content to a wide surface, and to improve the visibility (luminance) of the content.

Note that, in the embodiment of the invention, the display medium 1 is formed by a 3D printer. Accordingly, the shape and the accuracy of the partition P depend on the performance of the 3D printer that forms the partition. For example, by forming a thin thickness with respect to the Voronoi surface within a performance range of the 3D printer to form the partition P, it is possible to improve the visibility from the designated direction.

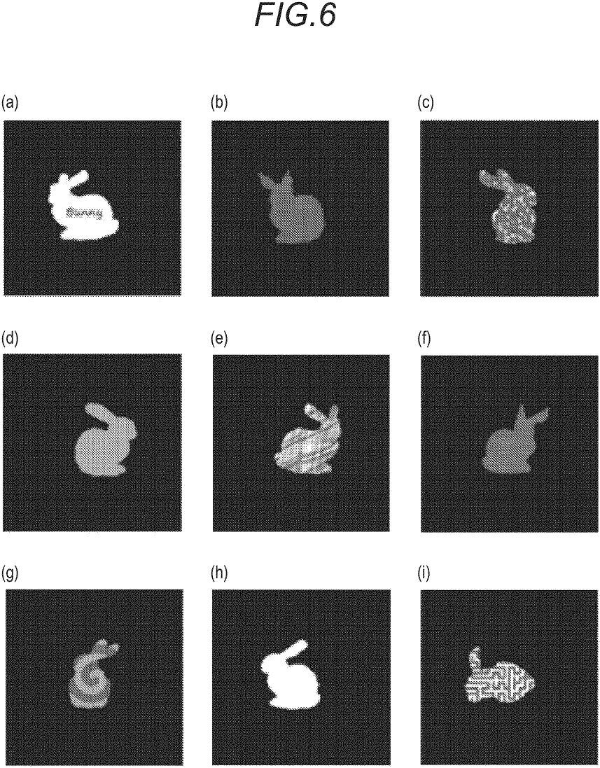

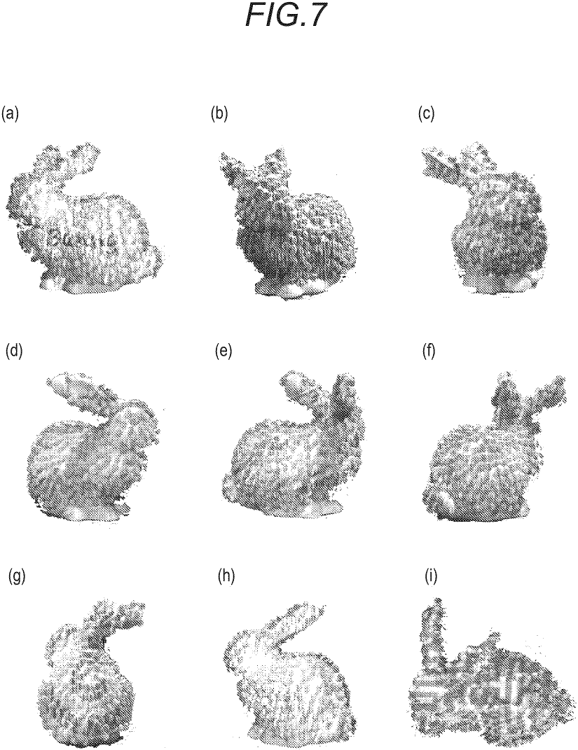

An example of the content that is displayed by the display medium 1 according to the embodiment of the invention will be described with reference to FIG. 6 and FIG. 7. In an example illustrated in FIG. 6 and FIG. 7, the display medium 1 illustrated in FIG. 4 displays different content pieces in a total of nine directions of eight directions (an elevation angle of 0 degrees) in which an azimuth angle on the side on the XY flat surface is shifted by each 45 degrees, and one direction (an elevation angle of 90 degrees) from the above (a Z axis). The display medium 1 illustrated in FIG. 7 is formed by the 3D printer.

FIG. 6 is a target image that the display medium 1 desires to display in each of the directions. Each of FIGS. 6(a) to 6(h) is a target image that is displayed in eight different directions of the azimuth angle on the side on the XY flat surface. FIG. 6(i) is a target image that is displayed with respect to the above.

FIG. 7 is content that the display medium 1 displays in each of the directions. Each of FIGS. 7(a) to 7(h) is the content that is displayed in eight different directions of the azimuth angle on the side on the XY flat surface, and corresponds to each of FIGS. 6(a) to 6(h). FIG. 7(i) is the content that is displayed with respect to the above, and corresponds to FIG. 6(i). The feature of each of the drawings in FIG. 6 can be expressed by each of the drawings in FIG. 7, and content pieces different from each other can be displayed in nine directions by one display medium 1.

Note that, in the example illustrated in FIG. 7, the partition P that is provided in the vicinity of the head, the back, or the like of the rabbit may have surfaces in all nine designated directions. On the other hand, the partition P provided on the side of the rabbit may have surfaces in three to four directions less than nine directions.

In the embodiment of the invention, the partition P has a surface that is exposed in each of the plurality of directions. In addition, since the surface to be exposed radially divides the space on the surface of the base material 2 in each of the plurality of directions, even in a case where the number of directions in which the display medium 1 displays the content increases, the area of the surface to be exposed can be maintained, and thus, it is possible to display the plurality of content pieces with a wide color range and a high luminance.

### Processing Device

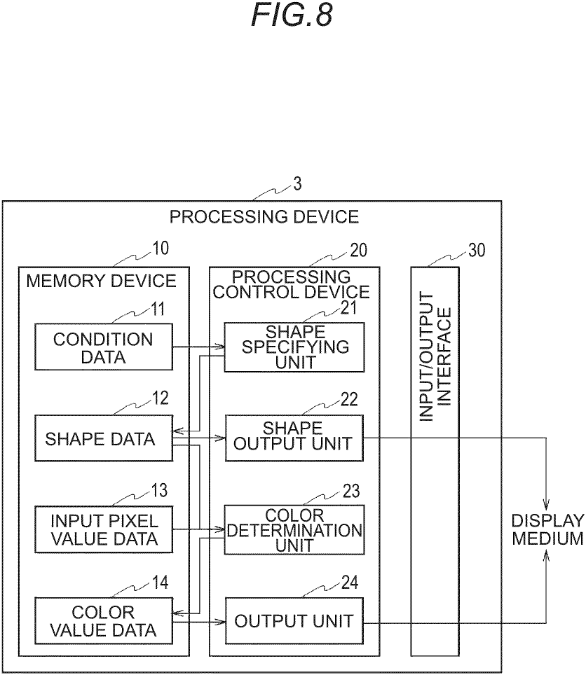

A processing device 3 according to the embodiment of the invention will be described with reference to FIG. 8. The processing device 3 calculates the position and the shape of the partition P for displaying the content in the designated direction. Further, the processing device 3 calculates the color of each sub-cell L of the display medium 1 such that an output image (content) that is displayed in each of the designated directions is close to a desired target image.

The processing device 3 calculates the Voronoi surface with respect to the generatrix on the designated direction, specifies the position and the shape of the partition P using the Voronoi surface as the center, and specifies the shape of the display medium 1. The processing device 3 divides the surface of the display medium 1 into a plurality of sub-cells L, and determines whether or not each of the sub-cells L is seen from each of the designated directions. The processing device 3 optimizes the color of each of the sub-cells L such that the content corresponding to each of the designated directions can be displayed by the color that is imparted to the sub-cell L that is seen from each of the designated directions.

Note that, in the embodiment of the invention, a case is described in which the processing device 3 calculates the position and the shape of the partition P and the color of the sub-cell L, but the invention is not limited thereto. For example, the position and the shape of the partition P, and the color of the sub-cell L may be calculated by manual calculation. In addition, the position and the shape of the partition P may be designed by using a tool such as a ruler or a compass.

The processing device 3 is a general computer including a memory device 10, a processing control device 20, and an input/output interface 30. By the general computer executing a processing program, functions illustrated in FIG. 8 are attained.

The memory device 10 is a read only memory (ROM), a random access memory (RAM), a hard disk, or the like, and stores various data pieces such as input data, output data, and intermediate data for the processing control device 20 to execute processing. The processing control device 20 is a central processing unit (CPU), and executes processing in the processing device 3 by reading and writing data that is stored in the memory device 10 or by inputting and outputting data with respect to the input/output interface 30.

The input/output interface 30 is an interface with an external device that performs input and output with respect to the processing control device 20. In the embodiment of the invention, the input/output interface 30 outputs the shape of the partition P and the color of the sub-cell L on the partition P to a manufacturing device of the partition P. The manufacturing device forms the partition P, on the basis of the position and the shape of the partition P, and the color of the display medium 1, which are input.

In the embodiment of the invention, the manufacturing device is a 3D printer. Note that, data of the shape of the display medium 1 and the color of the sub-cell L on the display medium 1 may be input to the manufacturing device from the processing device 3 through a communication network, a communication cable, or the like. Data relevant to the display medium 1 may be input to the manufacturing device through a memory medium such as a universal serial bus (USB) memory. In the embodiment of the invention, a case is described in which a 3D printer forms and tints the display medium 1, but the invention is not limited thereto. For example, the display medium 1 may be formed and tinted by devices different from each other.

The memory device 10 stores the processing program, and stores condition data 11, shape data 12, input pixel value data 13, and color value data 14. The condition data 11 and the input pixel value data 13 are applied in advance prior to the processing of the processing control device 20.

The condition data 11 includes data of the shape of the base material 2, and data of a condition required for determining the shape and the color of the partition P. The condition, for example, is the designated direction, the number of designated directions, the shape and the position of the cell C of the display medium 1, and the like.

The shape data 12 is data for specifying the shape of the display medium 1. The shape data 12 may be generated in a format that can be read by the manufacturing device.

The input pixel value data 13 is data of the target image of the output image that is output in each of the directions by the display medium 1. The input pixel value data 13 specifies a color value corresponding to each of the cells formed on the display medium 1, in each of the designated directions. The input pixel value data 13, for example, has a color value for each section having the same arrangement as that of each of the cells of the display medium 1. The color value, for example, is each value of three primary colors of RGB.

The color value data 14 specifies a color value that is applied to each of the sub-cells L of the display medium 1. As with the input pixel value data 13, for example, the color value is each value of three primary colors of RGB.

The processing control device 20 includes a shape specifying unit 21, a shape output unit 22, a color determination unit 23, and an output unit 24.

The shape specifying unit 21 calculates the position and the shape of the partition P, and specifies the shape of the display medium 1. The shape specifying unit 21 stores the shape data 12 for specifying the shape of the specified display medium 1 in the memory device 10. The shape specifying unit 21 specifies the shape of the display medium 1, in accordance with the performance of the manufacturing device that forms the display medium 1.

The shape output unit 22 outputs the shape data 12 generated by the shape specifying unit 21 to the manufacturing device through the input/output interface 30. The manufacturing device forms the display medium 1, on the basis of the input shape data 12.

The color determination unit 23 determines the color of each of the sub-cells L provided on the surface of the display medium 1 from the input pixel value data 13, generates the color value data 14, and stores the color value data in the memory device 10.

The output unit 24 outputs the color value data 14 generated by the color determination unit 23 to the manufacturing device through the input/output interface 30. The manufacturing device tints each of the sub-cells L of the display medium 1, on the basis of the input color value data 14.

### Shape Specifying Unit

The shape specifying unit 21 densely arranges packs including the partition P on the surface of the display medium 1, and calculates the position of the partition P. The shape specifying unit 21 calculates the shape of the partition P such that each of the partitions P has the surface that radially divides the space on the surface of the base material 2, in each of the directions in which the partition P is visually recognized. For example, the shape specifying unit 21, first, calculates Voronoi surface with respect to the generatrix provided on each of the designated directions. The shape specifying unit 21 further calculates a shape having a prescribed thickness with respect to the calculated Voronoi surface, as the shape of the partition P. In a case of specifying the position and the shape for providing each of the partitions P, the shape specifying unit 21 updates the position of the partition P such that the partitions P do not intersect with each other. A sum set is calculated from the position of each of the partitions P after being updated, the shape of each of the partitions P, and the shape of the base material 2, and the shape data 12 for specifying the shape of the display medium 1 is generated and is stored in the memory device 10.

In the embodiment of the invention, a case is described in which the position and the shape of the partition P provided in the display medium 1 are specified, but the display medium 1 and the partition P may be replaced with a general model and general component. For example, the shape specifying unit 21 may be applied to a case of specifying the shape of a model in which a plurality of components are added to the base material 2. The model may be a general tangible entity, or may be an object used in computer processing such as input to a 3D printer.

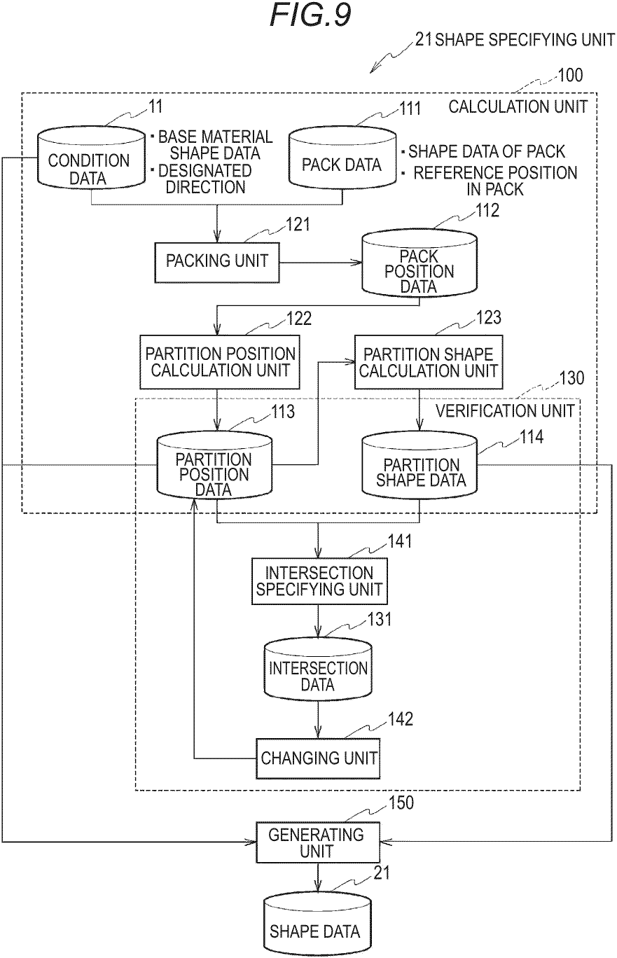

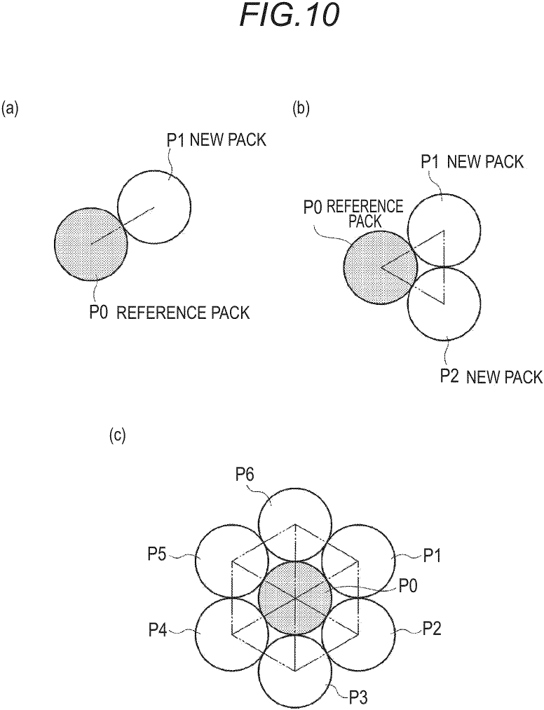

The shape specifying unit 21 will be described with reference to FIG. 9. The shape specifying unit 21 includes a calculation unit 100, a verification unit 130, and a generating unit 150.

### Calculation Unit

The calculation unit 100 calculates a position in which a plurality of partitions P (components) are provided and the shape of each of the partitions P, on the surface of the base material 2 having a three-dimensional shape.

In order for the display medium 1 to display content with a wide color range and a high luminance, it is preferable that many partitions P are provided on the surface of the base material 2. On the other hand, in a case where the partitions P intersect with each other, problems occur such that the color of the partition P is not seen due to the shadow of the other partition P, the shape of the display medium 1 is not capable of being specified and the display medium 1 is not capable of being generated by the 3D printer, and the like.

Therefore, the calculation unit 100 calculates a position in which a maximum number of partitions P are arranged such that the partitions P do not overlap with each other when seen from each observing point direction. In the embodiment of the invention, the partition P is densely arranged by repeating arrangement in which the partition is densely arranged locally (arrangement in which the surrounding partitions P are densely arranged with respect to one partition P) but not arrangement in which the partition P is densely arranged broadly (the calculation of the optimized solution for densely arranging the partition on the entire surface of the base material). In a case where the partition is densely arranged broadly, a large calculation cost may be required, but by repeating the arrangement in which the partition is densely arranged locally, a calculation load can be reduced.

The calculation unit 100 defines the pack including the partition P and densely arranges the pack when determining the arrangement of the partition P, and thus, is capable of densely arranging the partition P. Note that, the pack defined herein may include the maximum volume of the partition P that is set in accordance with the specification or the like. As illustrated in FIG. 5, the partition P is formed in a sphere having a radius r, and thus, the pack also has a spherical shape having a radius r.

The calculation unit 100 arranges the pack on the surface of the base material 2, and then, specifies the position of the partition P to be arranged in the pack. The calculation unit 100 specifies the shape of the partition P to have a surface (the Voronoi surface) in each of the designated directions in which the position is visually recognized, in accordance with the position of the partition P.

The calculation unit 100 includes the condition data 11, pack data 111, pack position data 112, partition position data 113, partition shape data 114, a packing unit 121, a partition position calculation unit 122, and a partition shape calculation unit 123.

As described with reference to FIG. 8, the condition data 11 includes the data for specifying the shape of the base material 2 (base material shape data), and the data of the condition required for determining the shape and the color of the partition P in the designated direction or the like.

The pack data 111 specifies the shape of a plurality of packs including the plurality of partitions P (components), respectively, and a reference position that is provided on the surface of the base material 2, in each of the packs. The reference position is a position to be referred to when arranging the pack on the base material, and is arranged such that the reference position is on the surface of the base material 2.

Here, the pack may have a shape including the partition P, and in order for denser arrangement, it is preferable that the pack is in contact with the partition P. In the embodiment, the partition P is formed in a virtual sphere having a radius r centered on the center Cs of the cell C illustrated in FIG. 5, and the pack has a spherical shape having a radius r. Note that, in the embodiment of the invention, the pack is a sphere, but may be in a shape not having a recess on the surface, such as a convex hull. Even in a case where there is a recess on the surface of the pack, it may be controlled such that the other pack is not in contact with the recess, and a recess may be allowed in the shape of the pack.

The pack position data 112 is data for specifying the position of each of the packs arranged on the surface of the base material 2, in accordance with a processing result of the packing unit 121. The pack position data 112, for example, includes the position of the surface of the base material 2 in which the reference position base material 2 is arranged.

The partition position data 113 is data for specifying the position of each of the partitions P, in accordance with a processing result of the partition position calculation unit 122. The partition position data 113 includes the position of the surface of the base material 2 in which the reference position of the partition P such as the center Cs of the cell C is arranged.

The partition shape data 114 is data for specifying the shape of each of the partitions P, in accordance with a processing result of the partition shape calculation unit 123. The partition shape data 114 includes a surface that can be visually recognized from the designated direction and is less likely to be visually recognized from the other designated direction, in each of the designated directions in which the position where the partition P is provided can be visually recognized. Such a surface, for example, is defined by the Voronoi surface.

The packing unit 121 arranges a reference position of one pack on the surface of the base material 2 with reference to the base material shape data of the condition data 11 and the pack data 111. The packing unit 121 executes processing of arranging the pack on the surface of the base material by using one pack that is already arranged as a reference pack to be in contact with the reference pack until a new pack in contact with the reference pack is not capable of being arranged. The packing unit 121 changes the reference pack, and repeats the processing until a new pack in contact with the pack that is already arranged is not capable of being arranged.

In a case where the new pack in contact with the pack that is already arranged is not capable of being arranged, the packing unit 121 generates the pack position data 112 including the position of each of the packs arranged on the base material 2.

Note that, the packing unit 121 does not arrange the actual pack and the actual base material, but performs calculation for arranging a pack object and a base material object, as computer processing, in order to determine the position of the partition P.

As illustrated in FIG. 10(a), the packing unit 121 arranges a reference pack P0 on the surface of the base material 2. The packing unit 121 arranges a new pack P1 to be in contact with the reference pack P0. In this case, a reference position of the reference pack P0 and the new pack P1 is positioned on the surface of the base material 2. The pack does not intersect with the other pack, but the pack and the surface of the base material are arranged to intersect with each other.

As illustrated in FIG. 10(b), the packing unit 121 arranges a new pack P2 to be in contact with the reference pack P0 and the new pack P1. A reference position of the new pack P2 is positioned on the surface of the base material 2. In a case where the packing unit 121 further repeats processing of arranging new packs P3 to P6 to be in contact with the reference pack P0 and the pack that is already arranged, arrangement as illustrated in FIG. 10(c) is obtained.

In FIG. 10(c), since a new pack contact with the reference pack P0 is not capable of being arranged, a pack (for example, the pack P1) other than the reference pack P0 is set to a new reference pack, and a new pack is arranged to be in contact with the pack P1 and the existing pack (here, P2 or P6).

Note that, an example illustrated in FIG. 10 is a case where the surface of the base material 2 is a flat surface. In a case where the surface of the base material 2 is a curved surface, the number of packs that can be arranged around the reference pack P0 is 5 or less.

As described above, by arranging the pack to be in contact with the existing pack, each of the packs can be densely arranged locally, and the pack can be densely arranged on the entire base material 2 without increasing a calculation cost.

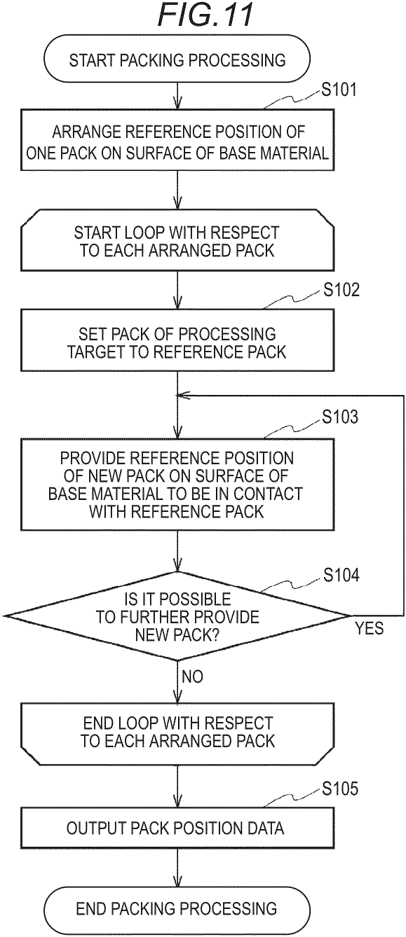

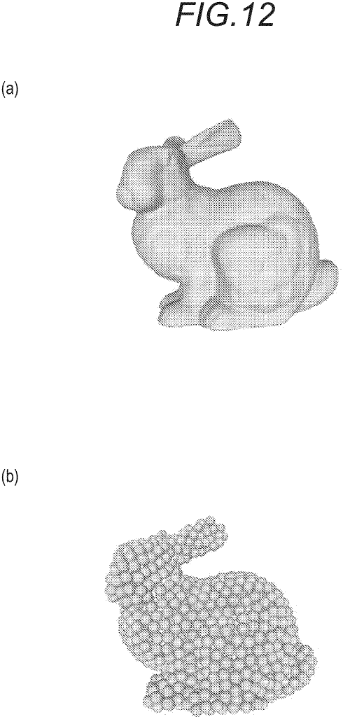

Packing processing of the packing unit 121 will be described with reference to FIG. 11.

First, in step S101, the packing unit 121 arranges a reference position of one pack on the surface of the base material 2.

The processing of step S102 to step S104 is repeated with respect to each of the packs that are already arranged.

In step S102, the packing unit 121 defines one pack that is already arranged as a reference pack. In step S103, a reference position of a new pack is provided on the surface of the base material 2 to be in contact with the reference pack. In step S104, the packing unit 121 determines whether or not it is possible to provide a new pack to be in contact with the reference pack defined in step S102. In a case where a new pack can be provided, in step S103, a new pack is provided. In a case where a new pack is not capable of being provided, in step S102, the packing unit 121 defines a new reference pack, and performs the processing of step S103 to step S104.

The processing of step S102 to step S104 is performed with respect to each of the packs that are already arranged, and in a case where a new pack is not capable of being arranged with respect to each of the packs that are already arranged, the process proceeds to step S105. In step S105, the packing unit 121 outputs the pack position data 112 including the position of each of the packs that are arranged in step S103.

In a case where the packing unit 121 generates the pack position data 112, the partition position calculation unit 122 specifies the position of the partition P (component), with reference to the pack position data.

The partition position calculation unit 122 calculates the position of the partition P in each of the packs, and generates the partition position data 113. The partition position calculation unit 122 calculates the position in which the partition P (component) is provided such that the surface of the partition P is positioned in the reference position of the pack, in accordance with the position of the pack arranged by the packing unit 121. In the embodiment of the invention, since the pack includes the maximum volume of the partition P, the position of the pack is specified as the position of the partition P. More specifically, the partition position calculation unit 122 calculates the position of the partition P such that an intersection point of each of the Voronoi surfaces of the partition P in FIG. 5 is set to the reference position of the pack.

A state where the pack is arranged on the surface of the base material 2 will be illustrated with reference to FIG. 12. FIG. 12(a) illustrates the shape of the base material 2, and FIG. 12(b) illustrates a state where the pack is arranged. As illustrated in FIG. 12(b), the pack can be densely arranged on the surface of the base material 2 by the packing unit 121.

In a case where the partition position calculation unit 122 generates the partition position data 113, the partition shape calculation unit 123 specifies the shape of each of the partitions.

The partition shape calculation unit 123 specifies the shape of the position, in accordance with the position in which each of the partitions P is provided. Since the partition P is provided on the base material having a three-dimensional shape, the designated direction in which the partition P can be visually recognized is limited in accordance with the position in which the partition P is provided. The partition P has a surface that is likely to be visually recognized from the designated direction to express a part of the content that is displayed in the designated direction that is visually recognized. By not having a surface relevant to a designated direction that is not visually recognized, more resources can be used to display one content piece, and high-definition content can be displayed.

A method for the partition shape calculation unit 123 to calculate the shape of the partition P in one cell will be described. The size of the cell C (a length in an X-axis direction and a length in a Y-axis direction), the designated direction, and the number (n) of designated directions are specified in advance. Here, the cell C has a square shape in which the length in the X-axis direction is the same as the length in the Y-axis direction. In addition, a distance on a diagonal line of the cell C is 2r. Note that, in a case where the base material 2 is not a flat surface, a virtual sphere is formed to intersect with the surface of the base material 2.

As illustrated in FIG. 5, a virtual sphere having a radius r centered on the center Cs of the cell C is assumed. An intersection point with the virtual sphere when the center Cs is observed from the designated direction is set to a generatrix corresponding to the designated direction. In the example illustrated in FIG. 5, the generatrix T1 is determined in the designated direction in which the observing point E1 is observed from the center Cs. Similarly, the generatrix T2 is determined in the designated direction in which the observing point E2 is observed from the center Cs. The generatrix T3 is determined in the designated direction in which the observing point E3 is observed from the center Cs.

In a case where the generatrix corresponding to each of the designated directions is determined, a three-dimensional Voronoi diagram is determined by dividing the space on the cell C into the regions, in accordance with which generatrix the region is close to. A portion in which the three-dimensional Voronoi diagram is cut by the virtual sphere having a radius r centered on the center Cs of the cell C is set to the structure (center/core) of the partition P.

The structure of the partition P is a part of the Voronoi surface in the Voronoi diagram in which the generatrix is virtually provided in each of the plurality of directions.

However, the structure of the partition P that is obtained by calculation is a so-called manifold, which does not have a thickness and is not capable of being molded. Therefore, a surface M is provided in the designated position of a distance 1, using the structure as the center. The surface M is formed such that a distance to the closest structure is 1. A three-dimensional shape including the surface M is the partition P. Note that, the distance 1 is sufficiently smaller than the radius r of the virtual sphere. In a case where the value of the distance 1 is large, the area of a surface to which a color is imparted decreases, and the visibility may decrease, and thus, it is preferable that the value of the distance is minimized. The value of the distance 1 depends on the performance of a device (a 3D printer) that forms the partition P, or the like.

Here, the surface M included in the partition P is expressed by Expression (1) using implicit modeling.

$$\text{M} = \{ x \vert ∥ x - s ∥ - l = 0 , s ∈ S \}$$

M: a surface configuring a partition
x: a point on M
S: a structure of the partition
1: the shortest distance from the structure of the partition to the surface M

The surface M of the partition P that is expressed by Expression (1) is a non-manifold surface. In Expression (1), the thickness of the partition P is 21. By setting the minimum resolution of the 3D printer to 21, the partition can be produced with the minimum error. Note that, Expression (1) is the description of a set, and on implementation, Expression (2) is subjected to triangle meshing by a polygonizer. Accordingly, each of the partitions P to be generated ensures a watertight mesh.

$$∥ x - s ∥ - l = 0$$

Note that, the shape of a specific partition P may be suitably changed. For example, as illustrated in FIG. 5, a plurality of shielding members that are formed in the partition P may be integrally formed, or may be individually formed.

In addition, the structure of the partition P includes an intersection point of the visual lines when the display medium 1 is observed from the plurality of directions. As illustrated in FIG. 1 and FIG. 2, in a case where the designated direction is provided symmetrically with respect to the center Cs of the cell C, the intersection point of the visual lines is provided on the center Cs of the cell C. In addition, the intersection point of the visual lines is the intersection point of the Voronoi surfaces in the Voronoi diagram in which the generatrix is virtually provided on each of the plurality of directions. In other words, the shielding member of the partition P is formed to radially divide the space on the cell from the center Cs of the cell C.

Partition shape calculation processing of the partition shape calculation unit 123 will be described with reference to FIG. 13. The processing illustrated in FIG. 13 is processing of calculating the shape of one partition P.

In step S201, the partition shape calculation unit 123 calculates the position of the virtual sphere having a radius r from the center Cs of the cell C of a processing target.

The partition shape calculation unit 123 repeats the processing of step S102 in each of the designated directions. In step S102, the shape specifying unit 21 calculates an intersection point between the visual line in which the cell C is observed from the designated direction of the processing target and the virtual sphere calculated in step S101, as a generatrix. In a case where the generatrix is calculated in each of the designated directions, the process proceeds to step S203.

In step S203, the partition shape calculation unit 123 calculates the Voronoi surface with respect to each of the generatrices calculated in step S202. In step S204, the partition shape calculation unit 123 specifies the shape in the virtual sphere calculated in step S201, among the Voronoi surfaces calculated in step S203, as the structure of the partition P that is provided on the cell C of the processing target. An inner side in which the Voronoi surface calculated in step S203 is cut by the virtual sphere calculated in step S201 is the structure of the partition P.

In step S205, the partition shape calculation unit 123 specifies the shape of the partition P by providing a thickness with respect to the structure of the partition P calculated in step S204. Here, a set of positions away from the structure of the partition P specified in step S204 by a prescribed distance is specified as the shape of the partition P. The specified shape of the partition is output as the partition shape data 114.

The partition shape calculation unit 123 generates the partition shape data 114 for specifying the shape of each of the partitions P.

### Verification Unit

The verification unit 130 verifies whether or not the 3D printer is capable of recognizing the shape of the display medium 1, regarding the position and the shape of the partition P calculated by the calculation unit 100. In addition, the verification unit 130 changes the position of the partition P such that the 3D printer is capable of recognizing the shape of the display medium 1.

The calculation unit 100 defines the pack including the partition P and densely arranges the pack to determine the position of each of the partitions P, and then, specifies the shape of each of the partitions P. Accordingly, the partitions P are in contact with each other, and the outer edges of the partitions P may intersect with each other. In a case where the outer edges of the partitions P intersect with each other, the watertightness of the display medium 1 is not capable of being ensured, and the 3D printer is not capable of grasping the surface shape of the display medium 1.

Therefore, the verification unit 130 changes the position of the partition P that intersects with the other partition P such that each of the partitions P is independent, and resolves the intersection between the partitions P. Accordingly, the verification unit 130 is capable of specifying the surface shape of the display medium 1 by updating to the position of the partition P in which the display medium 1 can be formed by the 3D printer.

The verification unit 130 includes the partition position data 113, the partition shape data 114, intersection data 131, an intersection specifying unit 141, and a changing unit 142.

The partition position data 113 and the partition shape data 114 are data generated by the calculation unit 100.

The intersection data 131 is data generated by the intersection specifying unit 141, and is data for specifying the partition P that intersects with the other partition P from the position and the shape of the plurality of partitions P contained in the display medium 1.

In a case where the partition P is added to the position specified by the partition position data 113, the intersection specifying unit 141 specifies the partition P that intersects with the shape of the other partition P. The intersection specifying unit 141 specifies the position and the shape of each of the partitions P and specifies the partition P that intersects with the other partition to be stored in the intersection data 131.

The changing unit 142 changes the position to which the partition P specified as intersecting with the other partition P is added to a position that does not intersect with the shape of the other partition P. The changing unit 142 may search for the position that does not intersect with the other partition P within a prescribed range from the partition P specified as intersecting with the other partition, or may search for the position by any of the surfaces of the base material 2. In the embodiment of the invention, since the shape of the partition P is specified from a relationship between the provided position and the designated direction, it is preferable that the partition is changed to a position in which the relationship with the designated direction is not greatly broken, even in the position after being changed.

In a case where there is no position to which the specified partition P is added, the changing unit 142 deletes the partition P specified as intersecting with the other partition. The changing unit 142 deletes data of the partition P of a deletion target from the partition position data 113 and the partition shape data 114.

### Generating Unit

The generating unit 150 generates the shape data 12 of the display medium 1 (model) by a sum-set operation of the shape of the base material 2, the position to which each of the partitions P (components) is added, and the shape of each of the partitions P (components). The position of each of the partitions is specified by the partition position data 113, and is the position calculated by the partition position calculation unit 122 or the position after being changed by the changing unit 142.

In a case where a sum set is calculated by adding the shape of each of the partitions P to the base material 2, additional processing occurs in accordance with the number of partitions P, and thus, a calculation cost is high. Therefore, the generating unit 150 calculates in advance the sum set of the shapes of each of the partitions P, and further calculates a sum set with the shape of the base material 2. Accordingly, the number of times of the processing of adding the partition P to the base material 2 is 1, and a calculation cost can be suppressed.

The shape data 12 generated by the generating unit 150 is data of the shape of the display medium 1 including the plurality of partitions P on the base material 2. In this case, the partition P has the surface in the designated direction in which the provided position can be visually recognized, and expresses some colors of the content displayed in the designated direction by the surface.

### Shape Specifying Method

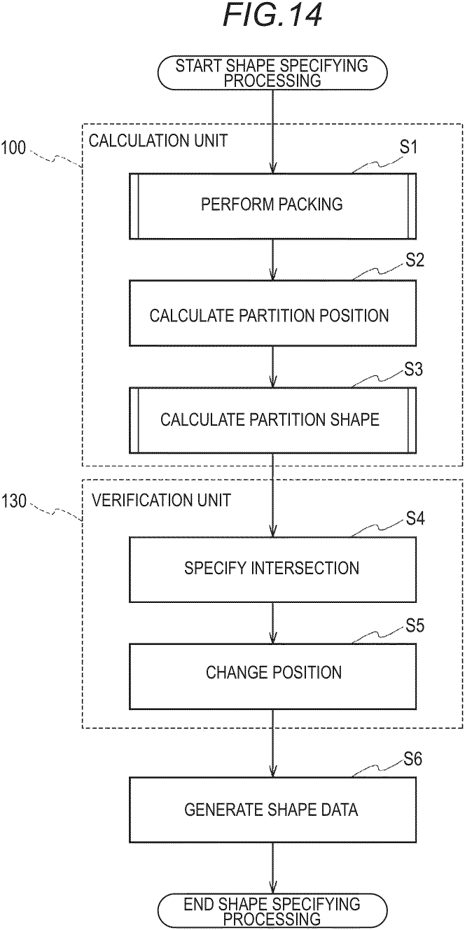

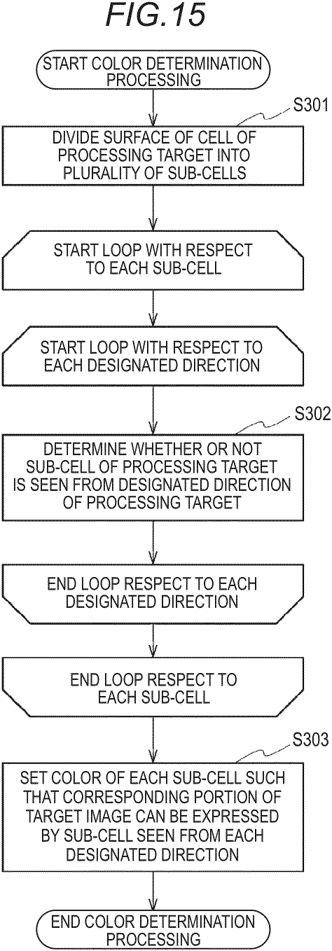

A shape specifying method of the shape specifying unit 21 will be described with reference to FIG. 14.

First, in step S1, the calculation unit 100 densely arranges the pack including the partition P on the surface of the base material 2 by the packing unit 121. Such processing is as described with reference to FIG. 11.

In step S2, the calculation unit 100 arranges the partition P in the pack arranged in step S1 and specifies the position of the partition by the partition position calculation unit 122. In step S3, the calculation unit 100 calculates the shape of the partition P by the partition shape calculation unit 123, in accordance with the position of the partition P calculated in step S2. Such processing is as described with reference to FIG. 13.

In a case where the position and the shape of the partition P is calculated, in step S4, the verification unit 130 specifies the partition P that intersects with the other partition P by the intersection specifying unit 141. In step S5, the verification unit 130 changes the position of the partition P that intersects with the other partition P and resolves the intersection by the changing unit 142.

In step S6, the generating unit 150 generates the shape data 12 of the display medium 1, in accordance with the shape of the base material 2, the position of the partition specified in step S2 or step S5, and the shape of the partition P specified in step S3.

In the shape data 12 generated as described above, the watertightness of the display medium 1 can be ensured, and the shape of the display medium 1 can be grasped by the 3D printer.

### Color Determination Unit

In the embodiment of the invention, the surface of the display medium 1 is virtually divided into the plurality of sub-cells L, and the sub-cell L is tinted with the color expressing the content. The sub-cell L is provided not only on the surface of the partition P but also on the surface of the base material 2 excluding the provided surface of the partition P.

The color determination unit 23, first, specifies the sub-cell L that is visually recognized from each of the plurality of directions. The color determination unit 23 determines whether or not each of the sub-cells L is seen from each of the designated directions. Further, the color determination unit 23 determines a color that is imparted to the sub-cell L such that a color formed by each color of the sub-cell L visually recognized from each of the plurality of directions is close to the color of the portion of the partition P of the content corresponding to each of the plurality of directions, as represented by Expression (3) described below.

The color determination unit 23 specifies a color value of the cell of the processing target in each of the target images displayed in each of the designated direction. The color of each of the sub-cells L of the cell is determined such that the mixing of the colors of the sub-cells L that can be visually recognized when the partition P is observed from the designated direction is the color value of the cell of the processing target in the target image corresponding to the designated direction. The same processing is repeated in each of the designated directions, and the color of each of the sub-cells L of the cell of the processing target is optimized. In addition, the color determination unit 23 similarly calculates a color that is imparted to each of the sub-cells of the display medium 1.

The color determination unit 23 generates the color value data 14 for specifying the optimized color of each of the sub-cells L. The color value data 14 specifies the color of each of the sub-cells L provided in each of the cells C of the display medium 1. The color determination unit 23 stores the generated color value data 14 in the memory device 10.

Note that, the display medium 1 according to the embodiment of the invention is capable of displaying excellent content in the designated direction, and is capable of displaying the content even in a case of being slightly away from the designated direction. For example, the display medium displays the content displayed in the designated direction by slightly modifying the content in a case of being away from the designated direction but far from the other designated direction. In a case where the content is less modified or in a case where the content is modified within a range in which the recognition of the content is less affected, the user is capable of understanding the semantic contents of the content even in a case where the content is modified.

On the other hand, for example, in a case where the display medium 1 is visually recognized from a direction far from any of the designated directions, such as visually recognizing the display medium 1 from the Voronoi surface, content that can be visually recognized by the user is different from the content intended by the display medium 1, and there are many cases in which the user is not capable of recognizing the semantic contents from the content.

In addition, in the embodiment of the invention, a case is described in which the color of the content is provided on the base material 2, but the invention is not limited thereto. For example, the color of the content may be imparted only to the surface of the partition P without providing the color on the base material 2.

As illustrated in FIG. 1 to FIG. 2, the surface that forms the partition P is virtually divided into the plurality of sub-cells L. In the partition P, a portion seen from at least one designated direction among the plurality of designated directions is divided into the plurality of sub-cells L. Each of the sub-cells L is imparted with the color expressing the content. It is not necessary that each of the sub-cells L is visually divided, and each of the sub-cells L may be virtually divided. For example, the same color may be imparted to the adjacent sub-cells L, and the sub-cells L may not be visually discriminated.

Note that, the plurality of sub-cells L illustrated in FIG. 5 are separated from each other, for description, but it is preferable that the plurality of sub-cells are formed adjacent to each other. In addition, the thickness of the sub-cell L illustrated in FIG. 5 is enlargedly illustrated in order to improve visibility, but the invention is not limited thereto. Even though it is not illustrated, in the embodiment of the invention, the sub-cell L is also provided on the base material 2 illustrated in FIG. 5.

The size of the sub-cell L is sufficiently small with respect to the distance from the observing point. The observing point is provided in a separated location in which juxtapositional additive color mixing is established.

The sub-cell L is a region that divides the surface of the display medium 1. As illustrated in FIGS. 1, 2, and the like, the sub-cell L is a region corresponding to the intersection point when the surface of the partition P is divided into the shape of a mesh. The sub-cell L may be a region in which the intersection point when the surface is divided into the shape of a mesh is set as a vertex, or may be a region centered on the intersection point.

A method for calculating the color that is imparted to the surface of the display medium 1 will be described.

First, in each of the designated directions, the sub-cell L that is visually recognized from the designated direction is specified. Here, by rendering the display medium 1 from each of the designated directions, the sub-cell L that is seen from the designated direction and the sub-cell L that is not seen from the designated direction are specified. In each of the designated directions assumed by the display medium 1, the sub-cell L that is seen from the designated direction and the sub-cell L that is not seen from the designated direction are specified.

Next, a method for specifying the color that is imparted to each of the sub-cells L will be described. A color value of the each of the sub-cells L is determined such that the color value of the cell in which the sub-cell L is positioned in the content corresponding to each of the designated directions can be expressed by the sub-cell L that is visually recognized from each of the designated directions. In this case, the color value of the content may be expressed by the plurality of sub-cells L that are visually recognized from the designated direction, in accordance with juxtapositional additive color mixing.

Specifically, the color of each of the sub-cells L is determined by Expression (3) such that a difference between a color Ac of the cell that is seen from the designated direction and a color B of the cell of the processing target of the content corresponding to the designated direction decreases. The color Ac of the cell is expressed by color mixing of the colors imparted to each of the sub-cells L that can be visually recognized from the designated direction.

$$\begin{matrix}\text{argmin} ∥ A c - B ∥ \\ c\end{matrix}$$

A: a matrix (n × p) indicating visibility of respective sub-cells from respective designated directions (1 when the sub-cell can be seen from the designated direction, and 0 when the sub-cell cannot be seen from the designated direction),
n: the number of designated directions
p: the number of sub-cells
c: colors (p × 3) of the respective sub-cells
B: a matrix (n × 3) of colors of cells of processing target of content in the respective designated directions

Note that, the color of each of the sub-cells L, for example, may be represented by a matrix of three parameters when representing with three primary colors such as red, green, and blue (RGB), or cyan, magenta, and yellow (CMY).

As described above, in a case where the color of each of the sub-cells L is determined for one cell, similarly, the color of each of the sub-cells L is determined for the other cell. In addition, in a case where there is a region in which the cell is not arranged, on the surface of the base material 2, the color determination unit 23 may also set the sub-cell L for the region, and as described above, may calculate a color that is imparted to the sub-cell L.

By arranging the cell that is formed and tinted as described above, the display medium 1 is capable of displaying different content pieces in each of the designated directions.

In the display medium 1 according to the embodiment of the invention, the partition P increases the area of the cell in which the partition P is provided and expresses a part of the content corresponding to the designated direction, and thus, it is possible to display the plurality of content pieces with a wide color range and a high luminance.

Color specifying processing of the color determination unit 23 will be described with reference to FIG. 15. An example illustrated in FIG. 15 is processing of determining the color of the sub-cell L of the surface of the base material 2 and the partition P in one cell.

In step S301, the color determination unit 23 divides the surface of the cell C of the processing target into the plurality of sub-cells L.

For each of the sub-cells L divided in step S301 and each of the designated directions, the processing of step S302 is executed. In step S202, the color determination unit 23 determines whether or not the sub-cell L of the processing target is seen from the designated direction of the processing target. In a case where the processing of step S302 is ended for each of the sub-cells L and each of the designated directions, the process proceeds to step S303.

In step S303, the color determination unit 23 sets the color of each of the sub-cells L such that a color value to be a target can be expressed by the sub-cell L that is seen from each of the designated directions. Here, the color value to be the target is a color value that is expressed by the cell of the processing target, among the color values of each of the content pieces displayed in each of the designated directions. The color value to be the target is provided in each of the designated directions. The color determination unit 23 optimizes the color value of each of the sub-cells L of the surface of the cell C to satisfy a requisite in which the color mixing of the colors of each of the sub-cells L seen from each of the designated directions is close to the color value of the cell of the processing target of the content displayed in each of the designated directions.

As described above, the processing device 3 calculates the shape of the partition P of each of the cells, and the color that is imparted to the cell, on the basis of Expression (1) and Expression (3), and thus, the display medium 1 is formed.

In addition, the display medium 1 according to the embodiment of the invention is capable of providing information of semantic contents different from each other in the plurality of directions, and thus, is capable of providing more information in a limited region.

### First Modification Example

In the embodiment of the invention, a case has been described in which the content that is displayed in each of the designated directions by the display medium 1 is a still image, but the invention is not limited thereto. For example, in a case where the surface of the partition P is formed as a display that is capable of displaying a video, and the surface of the partition can be dynamically changed, the content that is displayed in each of the designated directions by the display medium 1 may be a video. The display that is capable of displaying a video, for example, is a liquid crystal display, an organic electro-luminescence (EL) display, or the like.

In this case, each frame data piece that is simultaneously displayed among a plurality of target videos is a target image. The processing device 3 optimizes the color of each of the sub-cells L on the display medium 1 such that each frame data piece simultaneously displayed in each of the designated direction among the videos displayed by the display medium 1 is close to each of the target images.

In addition, the sub-cell L according to the embodiment of the invention is formed on the display. The sub-cell L is a pixel configuring the display or a group of a plurality of adjacent pixels.

### Second Modification Example

In the embodiment of the invention, a case has been described in which the display medium 1 is formed by the 3D printer, but the invention is not limited thereto. In the embodiment of the invention, the size of the display medium 1 is limited by the specification of the 3D printer, and the display medium 1 may be formed to have an arbitrary size.

For example, a display method of the display medium 1 according to the embodiment of the invention can be applied to a large-size display of several meters to several dozen meters, such as an advertisement billboard that is provided in a baseball stadium, a concert hall, an urban area, or the like. Such a large-size display is divided into a plurality of cells, and in each of the cells, partitions having surfaces corresponding to a plurality of designated directions are formed. The surface of such a partition is imparted with a color configuring an output image corresponding to the designated direction.

By applying the display method according to the embodiment to such a large-size display, it is possible to display content according to the position of each of the people to more people in a wider range.

For example, a display medium provided in the center of a hall is capable of displaying content pieces different from each other in each direction.

In addition, a large-size display provided in an urban area can be utilized in a road sign post or the like. It is possible to simultaneously provide different information pieces corresponding to different designated directions to people positioned in the different designated directions with respect to the large-size display. For example, the large-size display displays signals with respect to each of the different designated directions, and thus, a traffic light corresponding to a plurality of directions can be attained by one display.

In the display method according to the embodiment of the invention, information can be provided in a specific direction. For example, by providing the display medium according to the embodiment of the invention at an intersection in which a plurality of traffic lanes are mixed, the display medium is capable of displaying a signal by specifying each of the traffic lanes. Accordingly, a driver entering the intersection point can be prevented from mistaking signal display of the own traffic lane for signal display of the other traffic lane. In particular, the display medium 1 according to the embodiment of the invention has a three-dimensional shape, and thus, is capable of displaying content in an arbitrary direction. It is preferable that the display medium 1 is provided in a location that is visually recognized by people positioned in each direction, such as the intersection.

In addition, in the embodiment of the invention, a case has been described in which the display medium displays the content that can be directly visually recognized with the human eyes, but the invention is not limited thereto. The output image of the display medium may be captured by a camera, and people may recognize the content through the captured image. In a case where the display medium is gigantic, for example, people may recognize the content through aerial capturing of a drone or the like.

### Third Modification Example

The display medium according to the embodiment of the invention can also be applied to a technology that provides three-dimensional vision with the naked eyes.

The display medium according to the embodiment of the invention is capable of displaying different content pieces in the designated direction. A designated direction in which a display medium according to a third modification example displays content is matched to a difference between right and left eyesight angles of the user who visually recognizes the display medium. The display medium displays content for the right eye in which the user is capable of recognizing three-dimensional vision in a designated direction of the right eye, and displays content for the left eye in a designated direction of the left eye.

As described above, the display medium according to the third modification example may be applied to glasses-free 3D.

### Other Embodiments

As described above, the embodiments of the invention and the first to third modification examples have been described, but the discussion and the drawings configuring a part of the disclosure should not be construed as limiting the invention. Various alternative embodiments, examples, and operation technologies are obvious for a person skilled in the art from the disclosure.

For example, the processing device described in the embodiment of the invention, as illustrated in FIG. 8, may be configured on one hardware, or may be configured on a plurality of hardwares in accordance with the number of functions or processings thereof. In addition, the processing device may be attained on the existing processing system in which other functions are attained.

It is obvious that the invention includes various embodiments and the like that are not described herein. Accordingly, the technical scope of the invention is defined only by the matters used to specify the invention according to the claims that are valid from the above description.

### Reference Signs List

1 Display medium
2 Base material
3 Processing device
10 Memory device
11 Condition data
12 Shape data
13 Input pixel value data
14 Color value data
20 Processing control device
21 Shape specifying unit
22 Shape output unit
23 Color determination unit
24 Output unit
30 Input/output interface
100 Calculation unit
111 Pack data
112 Pack position data
113 Partition position data
114 Partition shape data
121 Packing unit
122 Partition position calculation unit
123 Partition shape calculation unit
130 Verification unit
131 Intersection data
141 Intersection specifying unit
142 Changing unit
150 Generating unit
A Space
B Shielding member
C Cell
Cs Center
L Sub-cell
P Partition
T Generatrix

1-11. (canceled)

12. A display medium displaying content pieces different from each other in a plurality of directions, the medium comprising:
a base material having a three-dimensional shape; and
a partition having a surface that radially divides a space on a surface of the base material in each of the plurality of directions, on the surface of the base material,
wherein a portion that is exposed when the display medium is observed from a prescribed direction among the plurality of directions is imparted with a color of content corresponding to the prescribed direction.

13. The display medium according to claim 12,
wherein the partition has a surface that radially divides the space on the surface of the base material in each direction in which the partition is visually recognized, among the plurality of directions.

14. The display medium according to claim 12,
wherein the partition is formed in a cell that is provided on a surface of the three-dimensional shape, and
a structure of the partition includes a part of a Voronoi surface in a Voronoi diagram using a point virtually provided on a line connecting points on the direction and the cell as a generatrix.

15. A processing device calculating a color that is imparted to the display medium according to claim 12,
wherein a surface of the display medium is virtually divided into a plurality of subcells,
a sub-cell that is visually recognized from each of the plurality of directions is specified, and
the processing device comprises
a color determination unit determining a color that is imparted to the sub-cell such that a color formed by each color of the sub-cell visually recognized from each of the plurality of directions is close to a color of a portion of content corresponding to each of the plurality of directions.

16. A program for calculating a color that is imparted to the display medium according to claim 12,
wherein a surface of the display medium is virtually divided into a plurality of subcells,
a sub-cell that is visually recognized from each of the plurality of directions is specified, and
the program allows a computer to function as
a color determination unit determining a color that is imparted to the sub-cell such that a color formed by each color of the sub-cell visually recognized from each of the plurality of directions is close to a color of a portion of content corresponding to each of the plurality of directions.

17. A processing device determining a position in which a plurality of components are provided, on a surface of a base material having a three-dimensional shape, the device comprising:
a memory device storing base material shape data for specifying a shape of the base material, and pack data for specifying a shape of a plurality of packs including the plurality of components, respectively, and a reference position that is provided on the surface of the base material, in the pack;
a packing unit arranging a reference position of one pack on the surface of the base material, with reference to the base material shape data and the pack data, executing processing of arranging the pack on the surface of the base material by using one pack that is already arranged as a reference pack to be in contact with the reference pack until a new pack in contact with the reference pack is not capable of being arranged, and repeating the processing until a new pack in contact with the pack that is already arranged is not capable of being arranged; and
a position calculation unit calculating a position in which the component is provided such that a surface of the component is positioned in the reference position of the pack, in accordance with a position of the pack arranged by the packing unit.

18. A processing device specifying a shape of a model in which a plurality of components are added to a base material, the device comprising:
a memory device storing shape data for specifying a shape of the base material, component shape data for specifying a shape of each of the components, and component position data for specifying a position in the base material to which the component is added;
an intersection specifying unit specifying a component intersecting with a shape of the other component when the component is added to the position specified by the component position data; and
a changing unit changing a position to which the specified component is added to a position not intersecting with the shape of the other component.

19. The processing device according to claim 18,
wherein when there is no position to which the specified component is added, the changing unit deletes the specified component.

20. The processing device according to claim 18, further comprising
a generating unit generating shape data of the model by a sum-set operation of the shape of the base material, a position to which each of the components after being changed by the changing unit is added, and the shape of each of the components.

21. The processing device according to claim 19, further comprising
a generating unit generating shape data of the model by a sum-set operation of the shape of the base material, a position to which each of the components after being changed by the changing unit is added, and the shape of each of the components.
